(19) United States
(12) Patent Application Publication
(10) Pub. No.: US 2026/0040606 A1
(43) Pub. Date: Feb. 5, 2026

(54) MIDDLE VOLTAGE TRANSISTOR WITH FIN STRUCTURE AND FABRICATING METHOD OF THE SAME

(71) Applicant: UNITED MICROELECTRONICS CORP., Hsin-Chu City (TW)

(72) Inventors: Wei-Hao Chang, Tainan City (TW); Wei-Che Chen, Kaohsiung City (TW); Kun-Szu Tseng, Tainan City (TW); Yao-Jhan Wang, Tainan City (TW)

(73) Assignee: UNITED MICROELECTRONICS CORP., Hsin-Chu City (TW)

(21) Appl. No.: 18/829,322

(22) Filed: Sep. 10, 2024

(30) Foreign Application Priority Data
Aug. 5, 2024 (CN) 202411061988.2

(51) Int. Cl. H01L 29/78; H01L 21/762; H01L 21/8234; H01L 29/417

(52) U.S. Cl. CPC H10D 30/62; H01L 21/76229; H10D 30/6219; H10D 84/0158; H10D 84/038; H01L 21/76232

(57) ABSTRACT

A middle voltage transistor with a fin structure includes a substrate. A fin structure protrudes from a surface of the substrate. A gate structure crosses the fin structure. A source is disposed at one side of the gate structure and embedded in the fin structure, and a drain is disposed at the other side of the gate structure and embedded in the fin structure. A second deep trench isolation is embedded in the substrate and adjacent to the source and drain. An isolation structure is embedded in the fin structure below the gate structure. The isolation structure includes a first deep trench isolation and a first shallow trench isolation extending from a sidewall of the first deep trench isolation toward the source.

### BACKGROUND OF THE INVENTION

### 1. Field of the Invention

The invention relates to a middle voltage transistor and a fabricating method of the same, and more particularly to a middle voltage transistor with a fin structure and a fabricating method of the same.

### 2. Description of the Prior Art

Transistor is one of the most important components in integrated circuits. Its function determines the quality of the circuits. Taking the metal-oxide-semiconductor field-effect transistor (MOSFET) as an example, when different bias are applied to the gate, the current between the source and the drain can be turned on or off.

MOSFETs are divided into low voltage, middle voltage and high voltage according to the maximum operating voltage they can withstand. MOSFETs can be used in different voltage ranges as switching components and amplifier circuits.

Because high voltage transistor withstands high voltages, they need to have a high breakdown voltage to withstand high input voltages. Middle voltage transistors have lower operating voltages than high voltage transistors. The working voltage of low voltage transistors is generally below 40 volts. As size of electronic products shrinks, size of transistors also need to be decreased to integrate more components on a limited chip area, thereby increase chip's function.

### SUMMARY OF THE INVENTION

In view of this, the present invention provides a middle voltage transistor with a fin structure to reduce the size of the device and increase the performance of the middle voltage transistor.

According to a preferred embodiment of the present invention, a middle voltage transistor with a fin structure includes a substrate. A fin structure protrudes from a surface of the substrate. A gate structure crosses the fin structure. A source is disposed at one side of the gate structure and embedded in the fin structure. A drain is disposed at the other side of the gate structure and embedded in the fin structure. A second deep trench isolation is embedded in the substrate, and wherein the second deep trench is adjacent to the source and the drain. An isolation structure is embedded in the fin structure below the gate structure, wherein the isolation structure includes a first deep trench isolation and a first shallow trench isolation extending from a sidewall of the first deep trench isolation toward the source.

According to another preferred embodiment of the present invention, a fabricating method of a middle voltage transistor with a fin structure includes providing a substrate. Next, the substrate is etched to form numerous shallow trenches in the substrate, wherein at least one fin structure is defined between the shallow trenches, and one of the shallow trenches is embedded within the fin structure. Later, the fin structure is etched to form a trench in the fin structure, wherein the trench is connected to the shallow trench embedded in the fin structure. After that, at least two of the shallow trenches are etched to form a first deep trench and a second deep trench, wherein the first deep trench is disposed in the fin structure and connected to the trench, and the second deep trench is disposed at one side of the fin structure. Subsequently, an insulating material layer is formed to fill in the shallow trenches, the trench, the first deep trench and the second deep trench. Then, the insulating material layer is etched back to make part of the fin structure protrude from the insulating material layer. Next, a gate dielectric layer is formed to encapsulate the fin structure which protrudes from the insulating material layer. Finally, a gate structure is formed to cover the fin structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 1A, FIG. 1B, FIG. 2, FIG. 2A, FIG. 2B, FIG. 3A, FIG. 3B, FIG. 4A, FIG. 4B, FIG. 5A, FIG. 6, FIG. 6A FIG. 6B depict a fabricating method of a middle voltage transistor with a fin structure according to a preferred embodiment of the present invention, wherein:

FIG. 1 depicts fabricating steps of etching substrate to form fin structures;

FIG. 1A depicts a sectional view taken along a line AA′ in FIG. 1;

FIG. 1B depicts a sectional view taken along a line BB′ in FIG. 1;

FIG. 2 depicts a fabricating stage following FIG. 1;

FIG. 2A depicts a sectional view taken along a line CC′ in FIG. 2;

FIG. 2B depicts a sectional view taken along a line DD′ in FIG. 2;

FIG. 3A depicts fabricating steps in continuous of FIG. 2A;

FIG. 3B depicts fabricating steps in continuous of FIG. 2B;

FIG. 4A depicts fabricating steps in continuous of FIG. 3A;

FIG. 4B depicts fabricating steps in continuous of FIG. 3B;

FIG. 5A depicts fabricating steps in continuous of FIG. 4A;

FIG. 5B depicts fabricating steps in continuous of FIG. 4B;

FIG. 6 depicts a top view of a fabricating step following FIG. 5A;

FIG. 6A depicts a sectional view taken along a line EE′ in FIG. 6; and

FIG. 6B depicts a sectional view taken along a line FF′ in FIG. 6.

### DETAILED DESCRIPTION

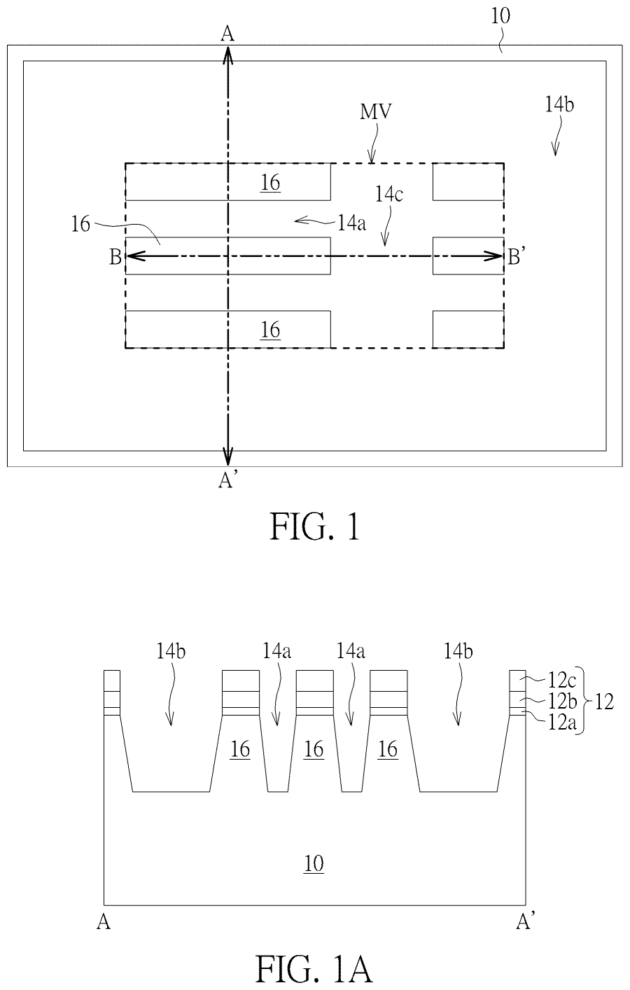

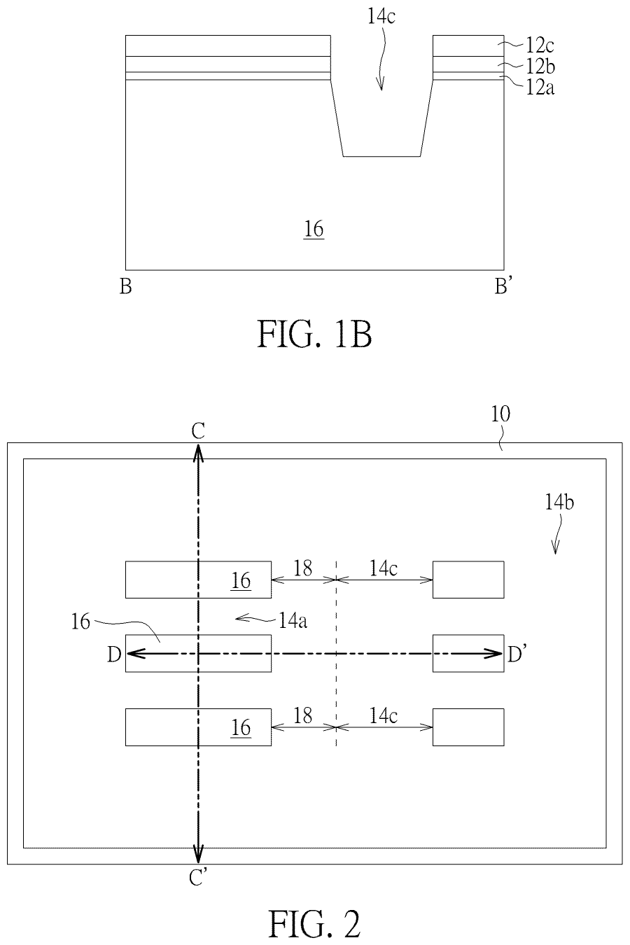

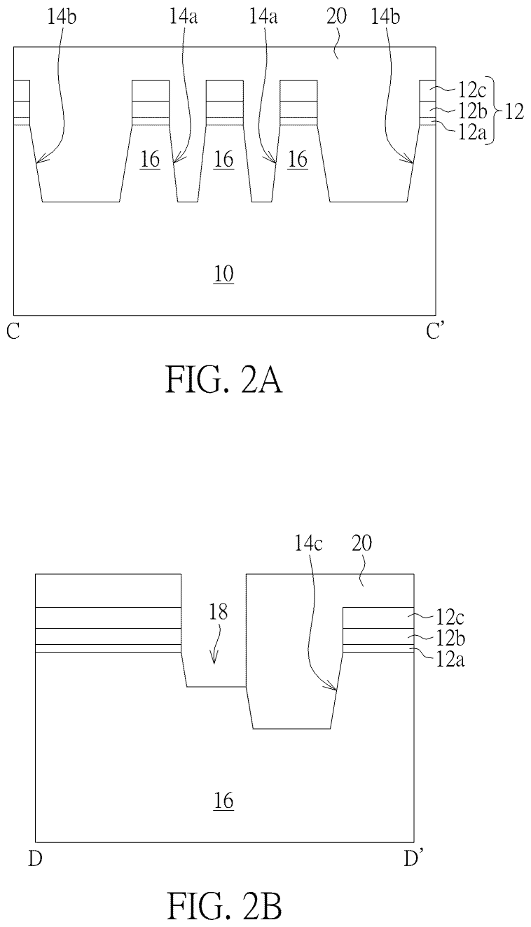

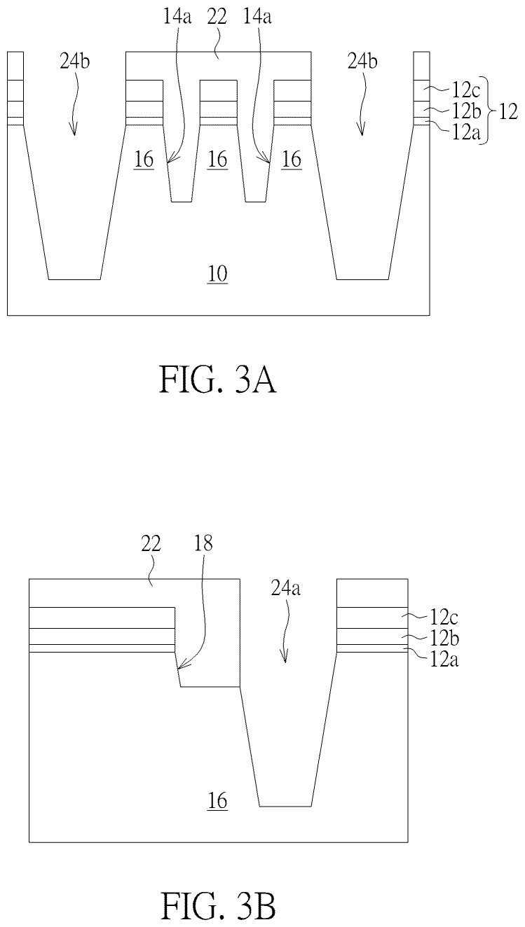

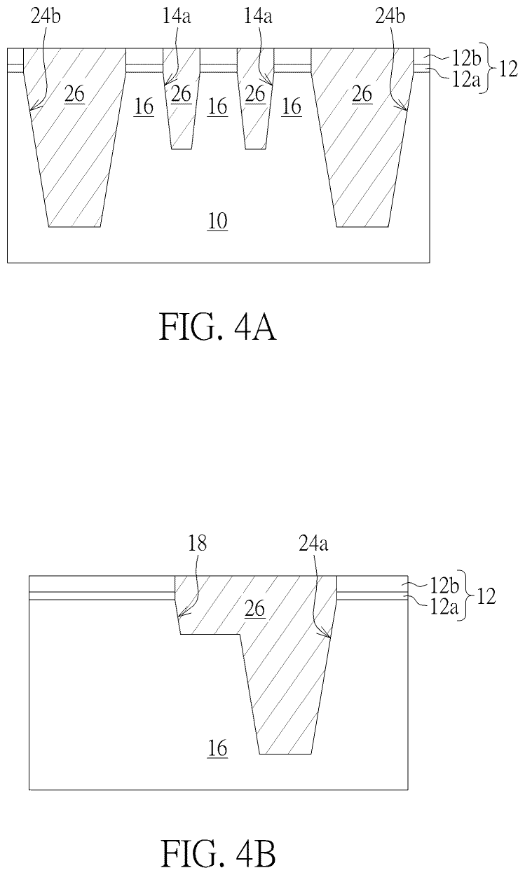

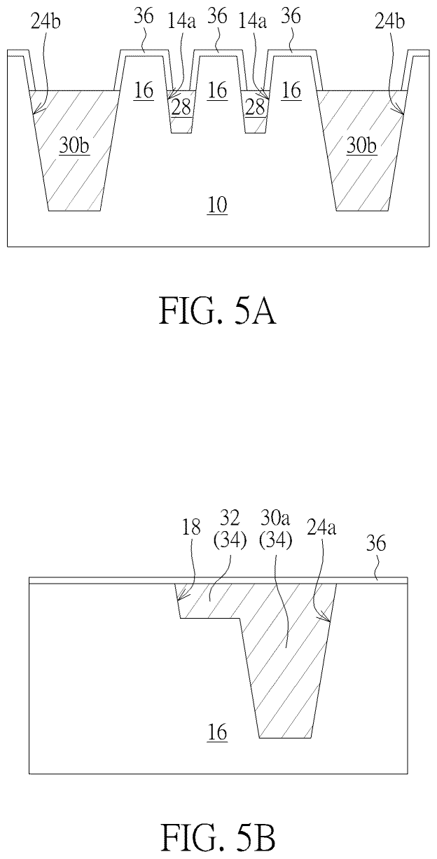

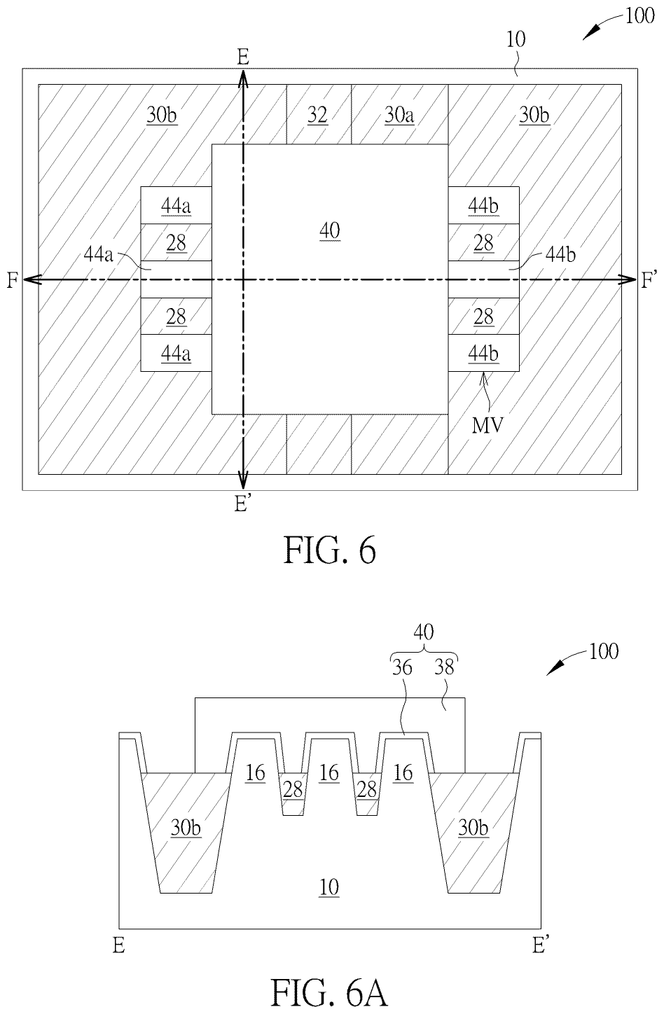

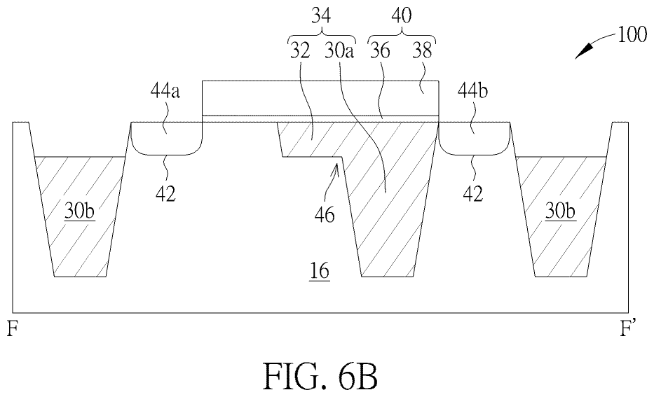

FIG. 1, FIG. 1A, FIG. 1B, FIG. 2, FIG. 2A, FIG. 2B, FIG. 3A, FIG. 3B, FIG. 4A, FIG. 4B, FIG. 5A, FIG. 6, FIG. 6A FIG. 6B depict a fabricating method of a middle voltage transistor with a fin structure according to a preferred embodiment of the present invention. FIG. 1A depicts a sectional view taken along a line AA′ in FIG. 1. FIG. 1B depicts a sectional view taken along a line BB′ in FIG. 1. FIG. 2A depicts a sectional view taken along a line CC′ in FIG. 2. FIG. 2B depicts a sectional view taken along a line DD′ in FIG. 2. FIG. 3A depicts fabricating steps in continuous of FIG. 2A. FIG. 3B depicts fabricating steps in continuous of FIG. 2B. FIG. 4A depicts fabricating steps in continuous of FIG. 3A. FIG. 4B depicts fabricating steps in continuous of FIG. 3B. FIG. 5A depicts fabricating steps in continuous of FIG. 4A. FIG. 5B depicts fabricating steps in continuous of FIG. 4B. FIG. 6 depicts a top view of a fabricating step following FIG. 5A. FIG. 6A depicts a sectional view taken along a line EE′ in FIG. 6. FIG. 6B depicts a sectional view taken along a line FF′ in FIG. 6.

FIG. 1 depicts fabricating steps of etching substrate to form fin structures. As show in FIG. 1, FIG. 1A and FIG. 1B, a substrate 10 is provided. Next, a patterned mask layer 12 is formed to cover the substrate 10 to define an area on the substrate 10 where the fin structure will be formed. The patterned mask layer 12 includes a silicon oxide layer 12a, a silicon nitride layer 12b and a silicon oxide layer 12c stacked in sequence from bottom to top. For simplicity of illustration, the patterned mask layer 12 is omitted in FIG. 1. Later, the substrate 10 is etched to form numerous shallow trenches 14a/14b/14c on the substrate 10 by taking the patterned mask layer 12 as a mask. The fin structures 16 are defined between the shallow trenches 14a/14b. As shown in FIG. 1, the shallow trench 14a is located between the fin structures 16. The shallow trench 14b surrounding the fin structures 16 defines a middle voltage transistor region MV (marked with dotted lines) on the substrate 10. Moreover, as shown in FIG. 1 and FIG. 1B, the shallow trench 14c is embedded in each fin structure 16.

As show in FIG. 2, FIG. 2A and FIG. 2B, a photoresist 20 is formed to cover part of each of the fin structures 16 and fill in the shallow trenches 14a/14b/14c. Therefore, each fin structure 16 next to the shallow trench 14c is exposed, and part of the sidewall of the shallow trench 14c is also exposed. For simplicity of illustration, the photoresist 20 is omitted in FIG. 2. After that, part of the sidewall of each fin structure 16 and the shallow trench 14c are etched to form a trench 18 in each fin structure 16. The trench 18 is connected to the shallow trench 14c.

As shown in FIG. 3A and FIG. 3B, the photoresist 20 is completely removed. Later, a photoresist 22 is formed to cover each fin structure 16 and fill the shallow trenches 14a and the trench 18. Now, the shallow trenches 14b/14c are exposed through the photoresist 22. Then, shallow trenches 14b/14c are etched to form a first deep trench 24a and a second deep trench 24b by taking the photoresist 22 as a mask. The first deep trench 24a is formed by etching the bottom of the shallow trench 14c to make the shallow trench 14c deeper. The second deep trench 24b is formed by etching the bottom of the shallow trench 14b to make the shallow trench 14b deeper. The first deep trench 24a is disposed in each of the fin structures 16. One first deep trench 24a is connected to one trench 18. The second deep trench 24b is disposed at one side of the fin structure 16 arranged first among all the fin structures 16 and is also disposed at one side of the fin structure 16 arranged last among all the fin structures 16.

As shown in FIG. 4A and FIG. 4B, the photoresist 22 is completed removed. Now, the shallow trench 14a, the first deep trench 24a, the second deep trench 24b and the trench 18 are exposed. Later, an insulating material layer 26 such as silicon oxide is formed to fill the shallow trench 14a, the first deep trench 24a, the second deep trench 24b and the trench 18 and cover the substrate 10. Later, the insulating material layer 26 is planarized by using the patterned mask layer 12 as an etching stop layer. During the planarization process, the topmost silicon oxide layer 12c of the patterned mask layer 12 is removed to make the remaining insulating material layer 26 aligned with the silicon nitride layer 12b of the patterned mask layer 12. At this time, the top surface of the fin structure 16 is lower than the top surface of the insulating material layer 26.

As shown in FIG. 5A and FIG. 5B, the remaining patterned mask layer 12 and the insulating material layer 26 are etched back to make part of the fin structure 16 protrude from the insulating material layer 26. In details, the patterned mask layer 12 is completely removed during the etching back. Moreover, the insulating material layer 26 embedded in the shallow trench isolation 14a and the second deep trench 24b is etched to a predetermined depth to make the fin structure 16 protrude from the insulating material layer. However, the insulating material layer 26 in the trench 18 and in the first deep trench 24a is not etched back. Therefore, the top surface of the insulating material layer 26 in the trench 18 and in the first deep trench 24a is aligned with the top surface of the fin structure 16. At this time, the remaining insulating material layer 26 in the shallow trench 14a becomes a shallow trench isolation 28. The remaining insulating material layer 26 filling in the first deep trench 24a becomes a first deep trench isolation 30a. The remaining insulating material layer 26 filling in the second deep trench 24b becomes a second deep trench isolation 30b. The remaining insulating material layer 26 filling in the trench 18 becomes a shallow trench isolation 32. The first deep trench isolation 30a and the shallow trench isolation 32 are both embedded in the fin structure 16. The first deep trench isolation 30a and the shallow trench isolation 32 together form an isolation structure 34. The second deep trench isolation 30b surrounds the fin structures 16 to define a middle voltage transistor region MV on the substrate 10 (please refer to FIG. 1). The shallow trench isolation 28 is disposed between the fin structures 16 to separate the fin structures 16. Later, a gate dielectric layer 36 is formed to cover the protruding fin structure 16.

As shown in FIG. 6, FIG. 6A and FIG. 6B, a gate electrode 38 is formed to cross the fin structure 16. The gate electrode 38 and the gate dielectric layer 36 form a gate structure 40. The gate structure 40 is formed by forming a gate electrode material layer (not shown) to cover the gate dielectric layer 36, the isolation structure 34, the second deep trench isolation 30b and the shallow trench isolation 28. The gate electrode material layer includes doped polysilicon. Later, the gate electrode material layer is patterned. The patterned gate electrode material layer serves as a gate electrode 38. The bottom of the gate structure 40 completely covers the top surface of the isolation structure 34. Then, two recesses 42 are formed in each of the fin structures 16 and respectively at two sides of the gate structure 40. Next, an epitaxial process is performed to form two epitaxial layers respectively in each of the two recesses 42 to serve as a source 44 and a drain 44b. Now, a middle voltage transistor 100 of the present invention is completed.

As shown in FIG. 6, FIG. 6A and FIG. 6B, a middle voltage transistor 100 of the present invention is provided. The middle voltage transistor 100 preferably works between 100 to 300 volts. The middle voltage transistor 100 includes a substrate 10. The substrate 10 includes a silicon substrate, a germanium substrate, a gallium arsenide substrate, a silicon germanium substrate, an indium phosphide substrate, a gallium nitride substrate, a silicon carbide substrate or a silicon-on-insulator substrate. Numerous fin structures 16 protrude from a surface of the substrate 10. A gate structure 40 crosses all fin structures 16. The gate structure 40 includes a gate electrode 38 and a gate dielectric layer 36. The gate electrode 38 is preferably doped polysilicon. The gate dielectric layer 36 is preferably silicon oxide. A source 44a is disposed at one side of the gate structure 40 and embedded in each fin structure 16. A drain 44b is disposed at the other side of the gate structure 40 and embedded in each fin structure 16. The source 44a and the drain 44b respectively include an epitaxial layer, such as silicon germanium or silicon carbide.

The second deep trench isolation 30b is embedded in the substrate 10 to define a middle voltage transistor region MV in the substrate 10. As shown in FIG. 6, the second deep trench isolation 30b surrounds part of the middle voltage transistor 100 of the present invention. The middle voltage transistor 100 includes numerous fin structures 16. Moreover, the second deep trench isolation 30b is adjacent to the drain 44b and the source 44a. Therefore, the second deep trench isolation 30b will be adjacent to and in contact with an end of each fin structure 16. Furthermore, the second shallow trench isolation 30b and the first shallow trench isolation 28 are respectively disposed at two sides of one fin structure 16. Alternatively, two shallow trench isolations 28 are disposed at two sides of one fin structure 16.

As shown in FIG. 6B, in the fin structure 16, an isolation structure 34 is embedded in the fin structure 16 below the gate structure 40. The isolation structure 34 includes a first deep trench isolation 30a and a shallow trench isolation 32 extending from a sidewall of the first deep trench isolation 30a toward the source 44a. The sidewall of the first deep trench isolation 30a and the bottom of the shallow trench isolation 32 form a corner 46. Although FIG. 6B only shows a sectional view of one of the fin structures 16, all fin structures 16 have the same structure. In addition, the depth of the first deep trench isolation 30a and the second deep trench isolation 30b are the same. The depth of shallow trench isolation 32 is preferably smaller than the depth of shallow trench isolation 28. Moreover, the bottom of the gate structure 40 completely covers the top surface of the isolation structure 34. The first deep trench isolation 30a of the isolation structure 34 contacts the drain 44b. The isolation structure 34 is closer to the drain 44b and farther from the source 44a. The isolation structure 34, the second deep trench isolation 30b and the shallow trench isolation 28 respectively preferably include insulating materials such as silicon oxide or silicon nitride.

The middle voltage transistor of the present invention uses fin structures as current channels. That is, the middle voltage transistor is formed by using numerous fin structures. Compared with planar middle voltage transistors, middle voltage transistors with fin structures can not only reduce component size and reduce process steps, but also improve the operating performance of middle voltage transistors.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A middle voltage transistor with a fin structure, comprising:
a substrate;
a fin structure protruding from a surface of the substrate;
a gate structure crossing the fin structure;
a source disposed at one side of the gate structure and embedded in the fin structure;
a drain disposed at the other side of the gate structure and embedded in the fin structure;
a second deep trench isolation embedded in the substrate, and wherein the second deep trench is adjacent to the source and the drain; and
an isolation structure embedded in the fin structure below the gate structure, wherein the isolation structure comprises a first deep trench isolation and a first shallow trench isolation extending from a sidewall of the first deep trench isolation toward the source.

2. The middle voltage transistor with a fin structure of claim 1, wherein the first shallow trench isolation are connected to the first deep trench isolation.

3. The middle voltage transistor with a fin structure of claim 1, wherein a bottom of the gate structure completely covers a top surface of the isolation structure.

4. The middle voltage transistor with a fin structure of claim 1, wherein a depth of the first deep trench isolation is the same as a depth of the second deep trench isolation.

5. The middle voltage transistor with a fin structure of claim 1, wherein the second deep trench isolation is adjacent to an end of the fin structure.

6. The middle voltage transistor with a fin structure of claim 1, wherein a second shallow trench isolation and a third shallow trench isolation are respectively disposed at two sides of the fin structure.

7. The middle voltage transistor with a fin structure of claim 6, wherein a depth of the first shallow trench isolation is smaller than a depth of the second shallow trench isolation.

8. The middle voltage transistor with a fin structure of claim 1, wherein the isolation structure is closer to the drain and farther from the source.

9. The middle voltage transistor with a fin structure of claim 1, wherein the sidewall of the first deep trench isolation and a bottom of the first shallow trench isolation form a corner.

10. A fabricating method of a middle voltage transistor with a fin structure, comprising:
providing a substrate;
etching the substrate to form a plurality of shallow trenches in the substrate, wherein at least one fin structure is defined between the plurality of shallow trenches, and one of the plurality of shallow trenches is embedded within the fin structure;
etching the fin structure to form a trench in the fin structure, wherein the trench is connected to the shallow trench embedded in the fin structure;
etching at least two of the plurality of shallow trenches to form a first deep trench and a second deep trench, wherein the first deep trench is disposed in the fin structure and connected to the trench, and the second deep trench is disposed at one side of the fin structure;
forming an insulating material layer to fill in the plurality of shallow trenches, the trench, the first deep trench and the second deep trench;
etching back the insulating material layer to make part of the fin structure protrude from the insulating material layer;
forming a gate dielectric layer encapsulating the fin structure which protrudes from the insulating material layer; and
forming a gate structure covering the fin structure.

11. The fabricating method of a middle voltage transistor with a fin structure of claim 10, wherein a first shallow trench isolation is formed by filling the trench with the insulating material layer, a first deep trench isolation is formed by filling the first deep trench with the insulating material layer, and a second deep trench isolation is formed by filling the second deep trench with the insulating material layer.

12. The fabricating method of a middle voltage transistor with a fin structure of claim 11, further comprising forming a source and a drain embedded in the fin structure and respectively disposed at two sides of the gate structure.

13. The fabricating method of a middle voltage transistor with a fin structure of claim 12, wherein in the fin structure, the first shallow trench isolation are connected to the first deep trench isolation, and the first shallow trench isolation extends from a sidewall of the first deep trench isolation toward the source.

14. The fabricating method of a middle voltage transistor with a fin structure of claim 13, wherein the sidewall of the first deep trench isolation and a bottom of the first shallow trench isolation form a corner.

15. The fabricating method of a middle voltage transistor with a fin structure of claim 11, wherein a bottom of the gate structure completely covers a top surface of the first shallow trench isolation.
